(19) United States
(12) Patent Application Publication
(10) Pub. No.: US 2026/0239659 A1
(43) Pub. Date: Aug. 13, 2026

(54) SEMICONDUCTOR STRUCTURE AND FABRICATION METHOD THEREOF

(71) Applicant: NANYA TECHNOLOGY CORPORATION, New Taipei City (TW)

(72) Inventor: Ying-Cheng Chuang, New Taipei City (TW)

(73) Assignee: NANYA TECHNOLOGY CORPORATION, New Taipei City (TW)

(21) Appl. No.: 19/048,965

(22) Filed: Feb. 10, 2025

(51) Int. Cl. H10D 30/62; H01L 21/324; H10D 30/01; H10D 64/27; H10D 64/66

(52) U.S. Cl. CPC H10D 30/6212; H10D 30/024; H10D 64/512; H10D 64/514; H10D 64/518; H10D 64/662; H10P 95/906

(57) ABSTRACT

A semiconductor structure is provided. The semiconductor structure includes a carrier substrate, a semiconductor fin structure, a gate insulation layer, and a gate structure. The semiconductor fin structure is disposed over the carrier substrate and extending along a first direction. A width of the semiconductor fin structure varies along a second direction perpendicular to a top surface of the carrier substrate, with a widest portion of the semiconductor fin structure located at a middle of the semiconductor fin structure. The gate insulation layer is disposed on the semiconductor fin structure. The gate structure is disposed on the gate insulation layer.

### BACKGROUND

### Technical Field

The present invention relates to a semiconductor structure and a fabrication method thereof.

### Description of Related Art

Fin field-effect transistor (FinFET) is a type of 3D transistor where the channel is shaped like a fin, allowing the gate to control the channel from three sides. This structure improves performance by reducing leakage current and enhancing switching efficiency, especially in smaller nodes, compared to traditional planar MOSFETs.

FinFETs are widely used in advanced semiconductor technologies for applications requiring low power consumption and high performance. These include smartphones, high-performance computing, AI, and IoT devices, where they offer better efficiency, faster processing, and longer battery life.

### SUMMARY

The present invention provides a semiconductor structure and its fabrication method. B adjusting the shape of the semiconductor fin structure, a larger effective channel width can be achieved.

In accordance of some embodiments of the present disclosure, a semiconductor structure includes a carrier substrate, a semiconductor fin structure, a gate insulation layer, and a gate structure. The semiconductor fin structure is disposed over the carrier substrate and extending along a first direction. A width of the semiconductor fin structure varies along a second direction perpendicular to a top surface of the carrier substrate, with a widest portion of the semiconductor fin structure located at a middle of the semiconductor fin structure. The gate insulation layer is disposed on the semiconductor fin structure. The gate structure is disposed on the gate insulation layer.

In some embodiments, a portion of the gate insulation layer is located between t widest portion of the semiconductor fin structure and the carrier substrate along the second direction.

In some embodiments, a portion of the gate structure is located between the widest portion of the semiconductor fin structure and the carrier substrate along the second direction.

In some embodiments, the semiconductor fin structure has a curved surface, and the gate insulation layer is disposed on the curved surface of the semiconductor fin structure.

In some embodiments, a dielectric layer is disposed between the carrier substrate and the semiconductor fin structure. The semiconductor fin structure is in contact with the dielectric layer, and a width of the semiconductor fin structure first increases and then decreases along the second direction as the semiconductor fin structure extends away from the dielectric layer.

In some embodiments, a dielectric layer is disposed between the carrier substrate and the semiconductor fin structure. A portion of the gate insulation layer is located between the widest portion of the semiconductor fin structure and the dielectric layer along the second direction.

In accordance of some embodiments of the present disclosure, a fabrication method of a semiconductor structure includes the following steps: forming a semiconductor layer over a carrier substrate; etching the semiconductor layer to form a semiconductor strip extending along a first direction over the carrier substrate, wherein the semiconductor strip has sidewalls perpendicular to a top surface of the carrier substrate; heating the semiconductor strip in a hydrogen ambient, causing a shape of the semiconductor strip to transform into a semiconductor fin structure, wherein a width of the semiconductor fin structure varies along a second direction perpendicular to the top surface of the carrier substrate, with a widest portion located at a middle of the semiconductor fin structure; forming a gate insulation layer on the semiconductor fin structure; and forming a gate structure on the gate insulation layer.

In some embodiments, a portion of the gate insulation layer is located between t widest portion of the semiconductor fin structure and the carrier substrate along the second direction.

In some embodiments, the fabrication method further includes the following steps: forming a dielectric layer on the carrier substrate; forming the semiconductor layer on the dielectric layer; forming a first mask layer on the semiconductor layer; forming a first photoresist layer on the first mask layer; using the first photoresist layer as a mask to etch the first mask layer, forming a patterned first mask layer that extends along the first direction; using the first patterned mask layer as a mask to etch the semiconductor layer, forming the semiconductor strip; forming a conductive material layer over the gate insulation layer; forming a second mask layer over the conductive material layer; forming a second photoresist layer on the second mask layer; using the second photoresist layer as a mask to etch the second mask layer, forming a patterned second mask layer that extends along a third direction; using the second patterned mask layer as a mask to etch the conductive material layer, forming the gate structure.

In some embodiments, a spacer is formed on sidewalls of the gate structure.

### BRIEF DESCRIPTION OF THE DRAWINGS

FIGS. 1A, 2A, 3A, 4A, 5A, 6A, 7A, and 8A illustrate top-down schematic views of various stages in the fabrication method of the semiconductor structure according to some embodiments of the present disclosure.

FIGS. 1B, 2B, 3B, 4B, 5B, 6B, 7B, and 8B are cross-sectional schematic views along line A-A′ in FIGS. 1A, 2A, 3A, 4A, 5A, 6A, 7A, and 8A, respectively.

FIG. 9 is a perspective schematic view of the semiconductor structure shown in FIGS. 8A and 8B.

FIG. 10 shows a cross-sectional schematic view of the semiconductor structure of another embodiment of the present disclosure.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

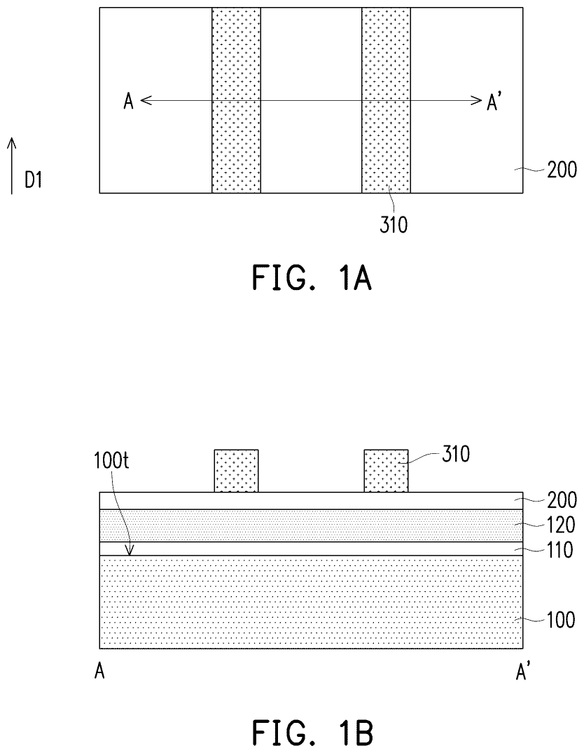

Referring to FIGS. 1A and 1B, a semiconductor layer 120 is formed over a carrier substrate 100. In some embodiments, the carrier substrate 100 may include wafers, glass, or the like. For example, the wafer may be composed of elemental semiconductors such as silicon or germanium, compound semiconductors like silicon carbide, gallium arsenide, gallium phosphide, indium phosphide, indium arsenide, and/or antimony indium, or alloy semiconductors like SiGe, GaAsP, AlInAs, AlGaAs, GaInAs, GaInP, and/or GaInAsP, or combinations thereof.

In some embodiments, the semiconductor layer 120 includes silicon, and the method for forming the semiconductor layer 120 includes an epitaxial growth process or other process.

In this embodiment, a dielectric layer 110 is formed on the carrier substrate 100 prior to the formation of the semiconductor layer 120, and the semiconductor layer 120 is then formed on the dielectric layer 110. In this embodiment, the semiconductor layer 120, dielectric layer 110, and carrier substrate 100 may collectively be referred to as a silicon-on-insulator (SOI) substrate. In some embodiments, the dielectric layer 110 includes an oxide (such as silicon oxide) or other suitable insulating materials. In certain embodiments, the dielectric layer 110 may also be referred to as a buried oxide (BOX) layer.

A first mask layer 200 is formed on the semiconductor layer 120. The first mask layer 200 may have a single-layer structure or a multi-layer structure. In some cases, the first mask layer 200 may be referred to as a hard mask layer. In certain embodiments, the first mask layer 200 includes an anti-reflection coating (ARC).

A first photoresist layer 310 is formed on the first mask layer 200. In this embodiment, the first photoresist layer 310 undergoes an exposure process and a development process, resulting in strip structures that extend along the first directions D1. The first direction D1 is parallel to the top surface 100t of the carrier substrate 100.

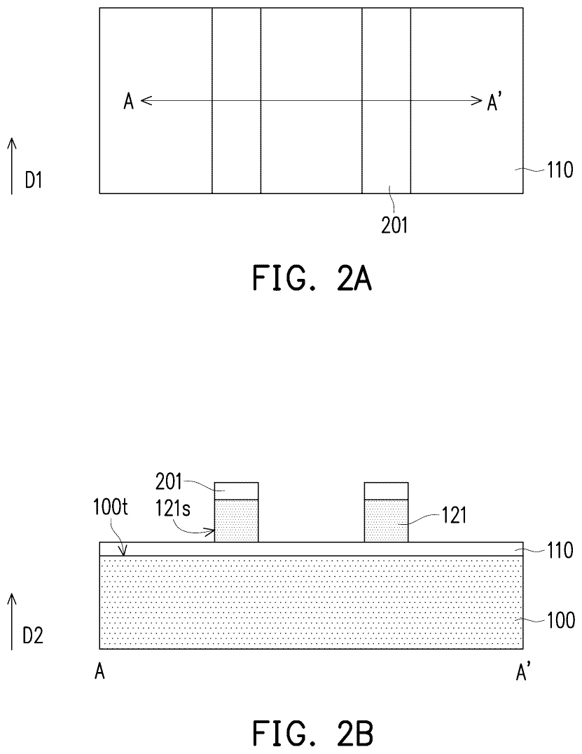

Referring to FIGS. 2A and 2B, the first photoresist layer 310 is used as a mask to etch the first mask layer 200, forming a patterned first mask layer 201 that extends along the first direction D1. The patterned first mask layer 201 is then used as a mask to etch the semiconductor layer 120, forming the semiconductor strip 121, which extends along the first direction D1 over the carrier substrate 100. The semiconductor strip 121 has sidewalls 121s that are substantially perpendicular to the top surface 100t of the carrier substrate 100. In this embodiment, the sidewalls 121s of the semiconductor strip 121 are substantially parallel to a second direction D2, which is perpendicular to the top surface 100t.

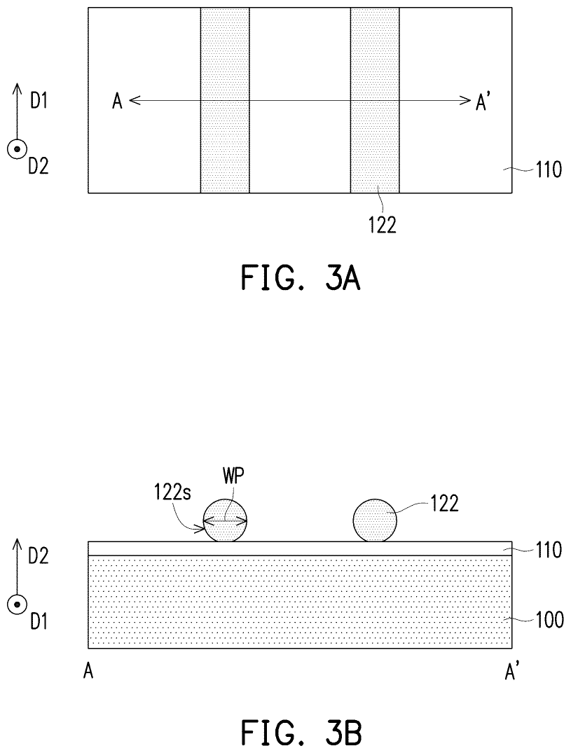

Referring to FIGS. 3A and 3B, the semiconductor strip 121 is heated in a hydrogen ambient, causing its shape to transform into a semiconductor fin structure 122. The sidewalls 121s are reshaped into curved surfaces 122s, turning the originally rectangular semiconductor strip 121 into an approximately cylindrical semiconductor fin structure 122. In this embodiment, the width of the semiconductor fin structure 122 varies along the second direction D2, with the widest portion WP located at the middle of the semiconductor fin structure 122. In this embodiment, the semiconductor fin structure 122 is in contact with the dielectric layer 110, and a width of the semiconductor fin structure 122 first increases and then decreases along the second direction D2 as the semiconductor fin structure 122 extends away from the dielectric layer 110.

In some embodiments, the semiconductor strip 121 undergoes annealing at 750° C.-900° C. under 550 Torr-750 Torr in an H₂ atmosphere for 4.5-8 minutes.

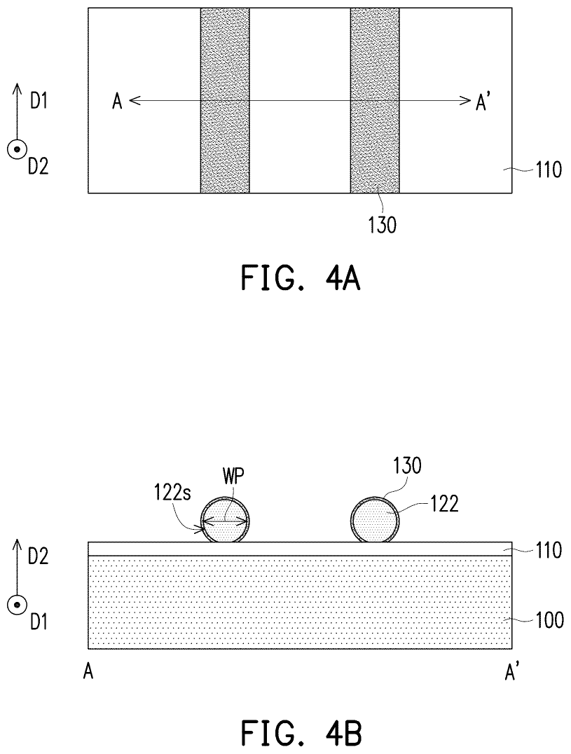

Referring to FIGS. 4A and 4B, a gate insulation layer 130 is formed on the curved surfaces 122s of the semiconductor fin structure 122. For example, methods for forming the gate insulation layer 130 include in-situ steam generated (ISSG) oxide, chemical vapor deposition (CVD), atomic layer deposition (ALD), physical vapor deposition (PVD), or other suitable techniques. In this embodiment, silicon oxide is formed on the curved surfaces 122s of the semiconductor fin structure 122 using ISSG; however, the disclosure is not limited thereto. In embodiments, a high dielectric constant (high-k) material is deposited on the curved surfaces 122s of the semiconductor fin structure 122. Examples of high-k materials include those with a dielectric constant higher than silicon dioxide (SiO₂), or greater than approximately 3.9. In some embodiments, the gate insulation layer 130 may include metal oxide, such as hafnium oxide (HfO₂), hafnium silicate (HSO), lanthanum oxide (La2O₃), lanthanum aluminate (LaAlO₃), zirconium oxide (ZrO₂), zirconium silicate (ZrSiO₄), aluminum oxide (Al₂O₃), or combinations thereof.

In this embodiment, the gate insulation layer 130 on one semiconductor fin structure 122 is separate from the gate insulation layer 130 on another semiconductor fin structure 122. However, this disclosure is not limited thereto. In other embodiments, the gate insulation layers 130 on adjacent semiconductor fin structures 122 may be connected.

In this embodiment, since the widest portion WP of the semiconductor fin structure 122 is located at the middle of the semiconductor fin structure 122, a portion of the gate insulation layer 130 is positioned between the widest portion WP of the semiconductor fin structure 122 and the carrier substrate 100 (or the dielectric layer 110) along the second direction D2.

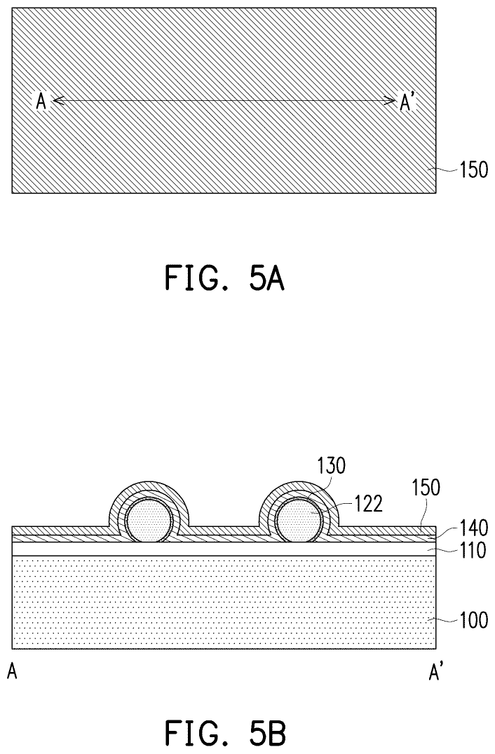

Referring to FIGS. 5A and 5B, a first conductive material layer 140 and a second conductive material layer 150 are formed over the gate insulation layer 130 and the dielectric layer 110. In some embodiments, the first conductive material layer 140 includes polysilicon, and the second conductive material layer 150 includes metal. However, the first conductive material layer 140 and the second conductive material layer 150 may also be made of other conductive materials.

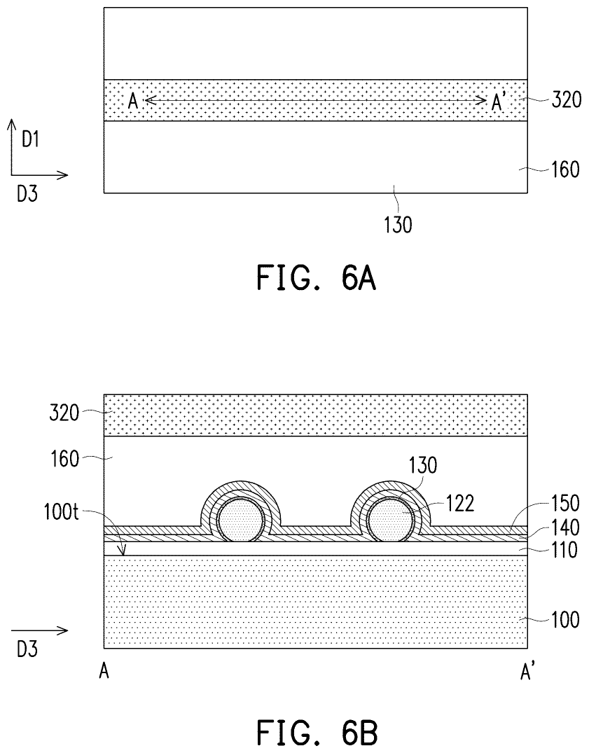

Referring to FIGS. 6A and 6B, a second mask layer 160 is formed over the first conductive material layer 140 and the second conductive material layer 150. In some embodiments, the second mask layer 160 comprises a nitride material (e.g., silicon nitride), but the disclosure is not limited to this. The second mask layer 160 may be made of other suitable insulating materials.

A second photoresist layer 320 is formed on the second mask layer 160. In this embodiment, the second photoresist layer 320 undergoes an exposure process and a development process, resulting in strip structures that extend along the third direction D3. The third direction D3 is parallel to the top surface 100t of the carrier substrate 100. In some embodiments, the third direction D3 is perpendicular to the first direction D1.

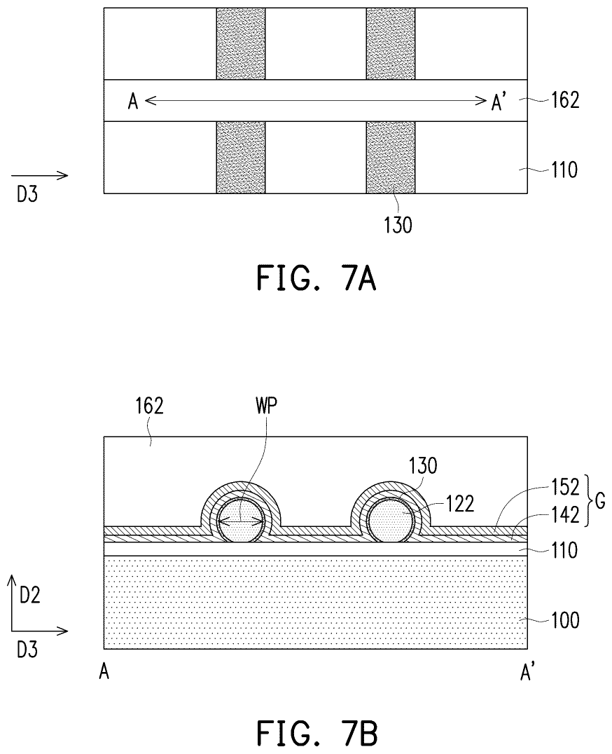

Referring to FIGS. 7A and 7B, the second photoresist layer 320 is used as a mask to etch the second mask layer 160, forming a patterned second mask layer 162 that extends along the third direction D3. The patterned second mask layer 162 is then used as a mask to etch the first conductive material layer 140 and the second conductive material layer 150, forming the gate structure G, which includes a first layer 142 and a second layer 152. The first layer 142 and the second layer 152 are formed by etching the first conductive material layer 140 and the second conductive material layer 150, respectively.

In some embodiments, a portion of the gate structure G is located between the widest portion WP of the semiconductor fin structure 122 and the carrier substrate 100 (or the dielectric layer 110) along the second direction D2. In some embodiments, the portion of the gate structure G is located between the gate insulation layer 130 and the carrier substrate 100 (or the dielectric layer 110) along the second direction D2. By adjusting the shape of the semiconductor fin structure 122, the effective channel width of the semiconductor fin structure 122 may be increased, thereby reducing the risk of leakage current in the semiconductor device and allowing the gate structure G to better control the current in the semiconductor fin structure 122.

In this embodiment, the gate structure G defines the source region, drain region, and channel region of the semiconductor fin structure 122. The channel region overlaps with the gate structure G, while the source region and drain region are positioned on either side of the channel region and do not overlap with the gate structure G. After forming the gate structure G, a doping process, such as light doping process, is performed on the source region and drain region.

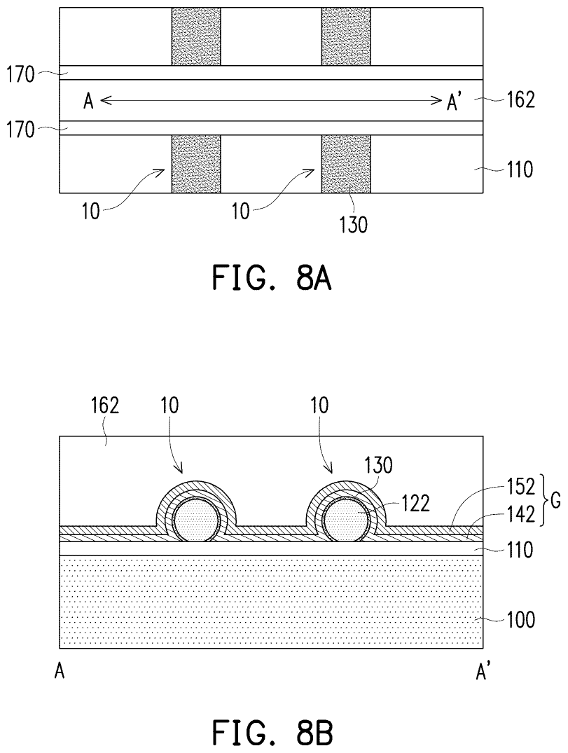

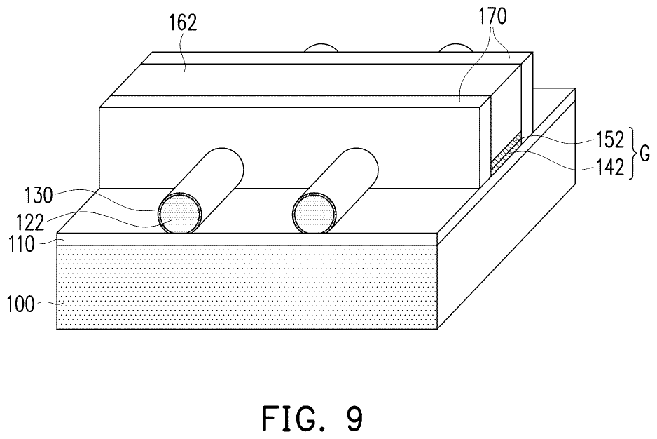

Next, referring to FIGS. 8A, 8B and 9, a spacer 170 is formed on the sidewalls of the gate structure G. After the spacer 170 is formed, a heavy doping process is performed on the source region and drain region.

In some embodiments, after performing the heavy doping process on the source region and drain region, an interlayer dielectric layer (not shown in the figures) is formed over the semiconductor structure 10 (i.e., the transistor). Then, source, drain, and gate contact structures (not shown in the figures) are formed within the interlayer dielectric layer, with the source contact, drain contact, and gate contact respectively connecting to the source region, drain region, and gate structure G of the semiconductor structure 10.

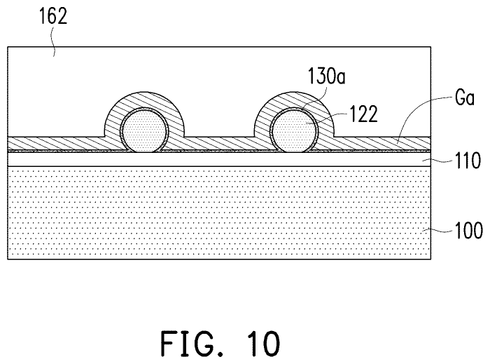

FIG. 10 shows a cross-sectional schematic view of the semiconductor structure 10a of another embodiment of the present disclosure. It should be noted herein that, in embodiments provided in FIG. 10, element numerals and partial content of the embodiments provided in FIG. 1A to FIG. 9 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 10, in this embodiment, the gate structure Ga is entirely made of metal, and the gate insulation layer 130a includes a high-k dielectric material, which blankets both the semiconductor fin structure 122 and the dielectric layer 110.

Based on the above, through the heating process in a hydrogen ambient, the semiconductor fin structure 122 takes on a shape with a wider middle and narrower top and bottom. This structure effectively increases the effective channel length of the semiconductor fin structure 122, thereby helping to mitigate leakage current issues.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a carrier substrate;
a semiconductor fin structure, disposed over the carrier substrate and extending along a first direction, wherein a width of the semiconductor fin structure varies along a second direction perpendicular to a top surface of the carrier substrate, with a widest portion of the semiconductor fin structure located at a middle of the semiconductor fin structure;
a gate insulation layer, disposed on the semiconductor fin structure; and
a gate structure, disposed on the gate insulation layer.

2. The semiconductor structure of claim 1, wherein a portion of the gate insulation layer is located between the widest portion of the semiconductor fin structure and the carrier substrate along the second direction.

3. The semiconductor structure of claim 1, wherein a portion of the gate structure is located between the widest portion of the semiconductor fin structure and the carrier substrate along the second direction.

4. The semiconductor structure of claim 1, wherein the semiconductor fin structure has a curved surface, and the gate insulation layer is disposed on the curved surface of the semiconductor fin structure.

5. The semiconductor structure of claim 1, further comprises:
a dielectric layer, disposed between the carrier substrate and the semiconductor fin structure, wherein the semiconductor fin structure is in contact with the dielectric layer, and a width of the semiconductor fin structure first increases and then decreases along the second direction as the semiconductor fin structure extends away from the dielectric layer.

6. The semiconductor structure of claim 1, further comprises:
a dielectric layer, disposed between the carrier substrate and the semiconductor fin structure, wherein a portion of the gate insulation layer is located between the widest portion of the semiconductor fin structure and the dielectric layer along the second direction.

7. A fabrication method of a semiconductor structure, comprising:
forming a semiconductor layer over a carrier substrate;
etching the semiconductor layer to form a semiconductor strip extending along a first direction over the carrier substrate, wherein the semiconductor strip has sidewalls perpendicular to a top surface of the carrier substrate;
heating the semiconductor strip in a hydrogen ambient, causing a shape of the semiconductor strip to transform into a semiconductor fin structure, wherein a width of the semiconductor fin structure varies along a second direction perpendicular to the top surface of the carrier substrate, with a widest portion located at a middle of the semiconductor fin structure;
forming a gate insulation layer on the semiconductor fin structure; and
forming a gate structure on the gate insulation layer.

8. The fabrication method of claim 7, wherein a portion of the gate insulation layer is located between the widest portion of the semiconductor fin structure and the carrier substrate along the second direction.

9. The fabrication method of claim 7, further comprising:
forming a dielectric layer on the carrier substrate;
forming the semiconductor layer on the dielectric layer;
forming a first mask layer on the semiconductor layer;
forming a first photoresist layer on the first mask layer;
using the first photoresist layer as a mask to etch the first mask layer, forming a patterned first mask layer that extends along the first direction;
using the first patterned mask layer as a mask to etch the semiconductor layer, forming the semiconductor strip;
forming a conductive material layer over the gate insulation layer;
forming a second mask layer over the conductive material layer;
forming a second photoresist layer on the second mask layer;
using the second photoresist layer as a mask to etch the second mask layer, forming a patterned second mask layer that extends along a third direction;
using the second patterned mask layer as a mask to etch the conductive material layer, forming the gate structure.

10. The fabrication method of claim 9, further comprising:
forming a spacer on sidewalls of the gate structure.
